(19) United States
(12) Patent Application Publication
(10) Pub. No.: US 2025/0230578 A1
(43) Pub. Date: Jul. 17, 2025

(54) Systems and Methods for Substituent Doping of Diamonds

(71) Applicant: Adam Khan, Palo Alto, CA (US)

(72) Inventor: Adam Khan, Palo Alto, CA (US)

(21) Appl. No.: 18/808,027

(22) Filed: Aug. 18, 2024

Related U.S. Application Data
(60) Provisional application No. 63/620,477, filed on Jan. 12, 2024.

(51) Int. Cl. C30B 31/22; C30B 29/04; C30B 33/02; C30B 33/04; H01L 21/04

(52) U.S. Cl. CPC C30B 31/22; C30B 29/04; C30B 33/02; C30B 33/04; H01L 21/0415

(57) ABSTRACT

Using the disclosed embodiments, co-doping nanocrystalline diamond (NCD) films with lithium, boron, and phosphorus leads to a significant improvement in electrical properties compared to existing approaches, even single-doped diamond. The combination of ion implantation and annealing results in enhanced carrier concentration, lower resistivity, and higher mobility, making these films highly suitable for advanced electronic applications. Implementation of the disclosed embodiments confirm that the disclosed co-doping strategy induces specific crystallographic orientations and dopant clustering, which contribute to the improved transport properties. The efficiency of the disclosed embodiments support emphasizing the role of crystallographic reorientation and dopant clustering in theoretical modeling in order to enhance diamond's electronic performance.

### RELATED PATENT APPLICATION AND INCORPORATION BY REFERENCE

This utility patent application claims priority from provisional patent application 63/620,477 filed on Jan. 12, 2024 the contents of which are incorporated herein by reference as if restated herein.

### COPYRIGHT AND TRADEMARK NOTICE

This application includes material which is subject or may be subject to copyright and/or trademark protection. The copyright and trademark owner(s) has no objection to the facsimile reproduction by any of the patent disclosure, as it appears in the Patent and Trademark Office files or records, but otherwise reserves all copyright and trademark rights whatsoever.

### BACKGROUND OF THE INVENTION

Diamond crystalline materials, with their wide bandgap of 5.47 eV and a host of extreme physical properties, stand out as a premier choice for advanced electronic and quantum applications. Renowned for the highest thermal conductivity (>2000 Wm\hat{ }−1K\hat{ }−1), exceptional electron and hole mobilities (>3000 cmV\hat{ }−1 s\hat{ }−1), and formidable breakdown field strength (10 MV cm\hat{ }−1), diamond's intrinsic attributes surpass those of conventional silicon and other wide-bandgap semiconductors. These properties position diamond as an ideal material for high-frequency field-effect transistors (FETs), power electronics, single-photon emitters, high-precision sensors, and cutting-edge quantum computing components. Despite its theoretical superiority and wide-ranging potential applications in harsh working conditions, the full exploitation of diamond's capabilities in devices like power diodes, photoconductive switches, and advanced detectors is hindered by substantial challenges. Fundamental obstacles include the difficulty in achieving shallow, thermally-activated n-type doping, controlling the quality and character of its crystalline structure, and a limited understanding of defect-related transport properties. Although doping with elements like boron, nitrogen, and phosphorus, as well as more exploratory halogens and lithium, has shown promise, a comprehensive understanding of the interplay between diamond's geometric and electronic properties—especially how these influence the band gap and defect states—is critically needed. As such, the development of diamond-based electronics and quantum devices requires not just incremental improvements in material processing and doping strategies but a revolutionary approach to harnessing and tailoring its unique properties for next-generation technologies.

### SUMMARY OF THE DISCLOSURE

The disclosed embodiments include the co-doping of lithium (Li), boron (B), and phosphorus (P) in nanocrystalline diamond (NCD) thin films, focusing on the enhancement of electrical properties and the underlying structural changes. Ion implantation was used for doping, followed by rapid thermal annealing (RTA) to achieve optimal dopant distribution. The films were characterized using Raman spectroscopy, secondary ion mass spectrometry (SIMS), and scanning transmission electron microscopy (STEM) to analyze doping profiles, crystal structure, and surface morphology. Electrical properties were evaluated through Van der Pauw measurements, revealing a high carrier concentration of 5.047×10\hat{ }18 cm\hat{ }−3, low resistivity of 1.228×10\hat{ }2 Ohm/sq, and high mobility of 347.47 cm\hat{ }2/Vs. These results indicate that co-doping significantly improves the electrical performance of diamond, making it a viable approach for diamond-based electronic devices. The disclosed embodiments highlight the impact of crystallographic orientation and dopant clustering on the observed properties.

In some disclosed embodiments, the disclosure herein presents a new and improved system and method for fabricating enhanced diamond semiconductor materials and devices. In accordance with one aspect of the approach, a specific percentage of the substituent donor atoms contribute to the lattice's conduction electrons instead of contributing to the competing intermediate band states, providing higher carrier mobility to be realized than the state of the art, wherein donors show ionization energies in the range of 0.15 to 0.3 eV, and where mobilities over 800 cm2/Vs can be realized at room temperature. The disclosure suggests broader applications and advantages of this approach in semiconductor technology.

In some disclosed embodiments, the disclosure herein, In another aspect of a disclosed approach, a method of fabricating substituent doped diamond semiconductor materials may include the steps of selecting a diamond Lattice material with RRQF of at least 133.2, introducing a minimal amount in the range of 1×10⁸/cm⁻² to 1×10¹¹ cm⁻², of interstitial dopant atoms to the diamond lattice to create interference with vacancy wavefronts, introducing a minimal amount in the range of 1×10⁸ cm⁻² to 1×10¹¹ cm⁻², of substituent acceptor strain dopant atoms, introducing a plurality of substituent donor dopant atoms in the range of 5×10¹⁰ to 5×10¹⁵ cm⁻², and pulsed laser irradiation using laser wavelengths of 550 nm or lower, wherein the combination of vacancy wavefront impedance and induced biaxial stress allow for substituent dopant geometries to realized and electronically activated by laser irradiance in lieu of thermal annealing techniques.

In another aspect of an approach, novel n-type and novel p-type substituent doping techniques are combined with novel fabrication methods for quantum optical defect creation and photonic components to create a monolithically integrated quantum photonic modulator device, where the quantum pair source, is modulated on chip, and where a fully diamond quantum photonic system is realized for the first time.

The benefits of the disclosed techniques and approach are broad and functional, promising significant advancements in the fields of high-frequency field-effect transistors, power electronics, single-photon emitters, high-precision sensors, and quantum computing components. The invention claims support this by detailing specific steps and conditions for manipulating diamond material properties, emphasizing an innovative combination of doping strategies, lattice manipulation, and annealing techniques.

The foregoing disclosure, including the drawings and detailed description, reveals various systems, methods, aspects, features, embodiments, and advantages related to the fabrication of diamond semiconductors. Those skilled in the art will recognize additional elements within this domain upon review of the provided materials. This disclosure intends to encompass all such supplementary systems, methods, aspects, features, embodiments, and advantages as part of this description and to include them within the ambit of the claims that follow.

### BRIEF DESCRIPTION OF THE DRAWINGS

The drawings provided are intended solely for illustrative purposes. It should be noted that the components depicted in these figures may not be to scale. The primary focus is on demonstrating the fundamental principles of the system described herein. In these illustrations, identical reference numerals are used to identify the same elements across various views.

FIG. 1 is a block diagram of a first embodiment of the method 100, for fabricating layers within diamond materials.

FIG. 2A is a perspective view of a prior art model of an intrinsic diamond wafer or plate upon which the method of FIG. 1 may be practiced.

FIG. 2B is an illustration of an intrinsic diamond lattice structure 206, which could be, but is not limited to, an intrinsic diamond lattice structure of diamond layer 202.

FIG. 2C is an illustration of an intrinsic diamond lattice structure 212, which could be, but is not limited to, an intrinsic diamond lattice structure of diamond layer 202.

FIG. 2D is an illustration of a section of intrinsic diamond molecular crystal structure 218 deposited by Chemical Vapor Deposition (CVD) method, which could be, but is not limited to, a section of intrinsic diamond wafer or plate 200.

FIG. 2E is a model of the intrinsic diamond electronic band gap 230, which could be, but is not limited to, the intrinsic diamond wafer or plate 200 and the diamond layer 202.

FIG. 3A is a perspective view of a model of a doped diamond wafer or plate 300, such as may be fabricated by subjecting the intrinsic diamond wafer or plate 200 to method 100.

FIG. 3B is an illustration of a substituent doped diamond lattice structure 308, such as may be fabricated by subjecting the intrinsic diamond lattice structure of 206 to method 100.

FIG. 3C is an illustration of a section of substituent doped diamond molecular crystal structure 318, such as may be fabricated by subjecting the intrinsic diamond molecular crystal structure of 218 to method 100.

FIG. 4 is an energy level diagram of the diamond band gap 400.

FIG. 5 shows a block diagram of a second embodiment of the method 500 for fabricating doped layers within diamond material.

FIG. 6A, FIG. 6B and FIG. 6C show a block diagram of a third embodiment of the method 600 for fabricating doped layers within diamond materials.

FIG. 7A shows a top view of an exemplary model of an integrated quantum photonic modulator device 700 that may be fabricated according to the method 600.

FIG. 7B. shows a side view of an exemplary model of a p-i-n phase shifter 712, which may be the P-i-n phase shifter 706 of integrated quantum photonic modulator device 700, that may be fabricated according to the method 600.

### REFERENCE NUMERALS IN THE DRAWINGS

These and other aspects of the present invention will become apparent upon reading the following detailed description in conjunction with the associated drawings.

### DETAILED DESCRIPTION OF EMBODIMENTS OF THE INVENTION

The following detailed description is directed to certain specific embodiments of the invention. However, the invention can be embodied in a multitude of different ways as defined and covered by the claims and their equivalents. In this description, reference is made to the drawings wherein like parts are designated with like numerals throughout.

Unless otherwise noted in this specification or in the claims, all of the terms used in the specification and the claims will have the meanings normally ascribed to these terms by workers in the art.

Unless the context clearly requires otherwise, throughout the description and the claims, the words “comprise,” “comprising” and the like are to be construed in an inclusive sense as opposed to an exclusive or exhaustive sense; that is to say, in a sense of “including, but not limited to.” Words using the singular or plural number also include the plural or singular number, respectively. Additionally, the words “herein,” “above,” “below,” and words of similar import, when used in this application, shall refer to this application as a whole and not to any particular portions of this application.

The following description combines and references the drawings to illustrate and teach one or more specific embodiments of the present application. These embodiments, offered not to limit but only to exemplify, are presented in sufficient detail for those skilled in the art to practice as claimed. The description aims to make the objects, technical solutions, and advantages of these embodiments clear and comprehensible. It may omit certain information known to those of skill in the art for brevity and assumes the examples were conducted under conventional conditions or those recommended by the manufacturer, using commercially available conventional products. The focus is on clarity and completeness, providing a technical understanding while acknowledging the expertise of the intended audience, and that those skilled in the art can also obtain other related drawings based on the drawings without inventive efforts.

The development of electronic and optical defects in diamond semiconductor in the prior art has limitations, where the main activities include: the theoretical ionization energies of potential donor dopants such as nitrogen, phosphorous, lithium and sodium, with theorized activation energies of 1.7 eV, 0.2-0.6 eV, 0.1 eV, and 0.3 eV, respectfully, acceptor dopants such as Boron, with theorized activation energy 0.1-0.37 eV, and optical vacancy-dopant defects such as nitrogen-vacancy (N-V), silicon-vacancy (Si-V) and germanium-vacancy (Ge-V), with a range of electron-spin coherence times based on various factors such as concentrations and interrelated band splitting effects. In practice, only deep donor activation energies with low carrier densities at ambient conditions are demonstrated, with attempts at incorporating higher donor or acceptor dopant concentrations leading to graphitic-like band bending, decreased carrier mobilities with charge carrier transport via hopping conduction, and further compromised electronic properties, especially noticeable with temperature variations. These dopants are invariably introduced alongside compensating/passivating defects such as interstitial-vacancy defects, vacancy chains and dislocation fronts, which further degrade the electronic performance and erode the inherent advantages of diamond materials. Moreover, the ambition to enhance the density of optical defect centers in diamond quantum systems invariably clashes with the need to maintain long carrier lifetimes or long electron-spin coherence times, resulting in detrimental trade-offs. Despite the theoretical promise of diamond crystalline materials for advanced electronic and quantum devices, practical demonstrations have consistently grappled with significant technological barriers due to fundamental gaps in diamond defect knowledge.

Another major failing of the prior art can be seen in the dubious nature of diamond crystalline geometry and defect incorporation therein, where potential dopant donors such as Li and N show electronic band gap states in polycrystalline diamond systems not replicated in the single crystal diamond system of any orientation, such as nitrogen incorporation in ultrananocrystalline diamond, so-called N-UNCD. Additional manifestations of this problem include phosphorous doping concentration versus ionization efficiency in (111) oriented versus (100) oriented single crystal diamond. This constitutes a major failing of prior art as claims must particularly point out and distinctly define the metes and bounds of the subject matter that will be protected, and materials ranging from single-crystal diamond to various forms of polycrystalline diamond and mixed-amorphous diamond-like materials, such as diamond-like-carbon, so-called DLC, and so-called Q-Carbon, each with their unique sp² and sp³ bonding states, present diverse mechanical, optical, and electronic characteristics. These enduring challenges not only reflect a gap in achieving the full potential of diamond materials but also underscore the serious implications for the advancement of semiconductor and quantum technologies. The persistent defects, particularly in nanocrystalline films, compromise not only the electronic and optical properties but also the mechanical integrity, significantly limiting the application of diamond in demanding environments. The collective struggle to achieve full activation of dopants, maintain high carrier mobilities and coherence, ensure long-term stability, and preserve the mechanical robustness of diamond films represents a critical bottleneck in unlocking the full suite of diamond's exceptional attributes.

Accordingly, there is an unmet need presently in addressing these multifaceted challenges in enabling shallow substituent dopant materials and thereby enabling novel power electronic devices, amongst other applications.

The substituent doped diamond, the preparation method thereof, the semiconductor and/or semimetal material and devices in the embodiments of the present are specifically described below.

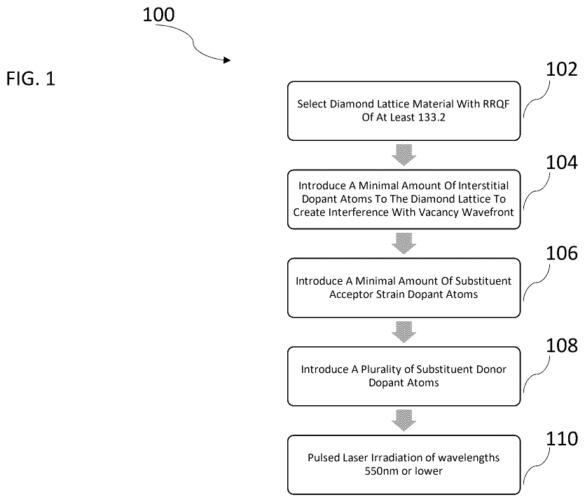

FIG. 1 shows a block diagram of a first embodiment of the method 100, for fabricating layers within diamond materials. The method 100 may include a first step 102 of selecting a material with diamond lattice and RRQF of at least 133.2. The diamond material exhibits properties characteristic to intrinsic diamond, where intrinsic diamond is diamond that has not been intentionally or unintentionally doped. Doping may introduce impurities and/or impurity-vacancy defects for the purpose of giving the diamond material electrical or optical characteristics, such as, but not limited to, n-type, p-type, quantum excitonic characteristics. The diamond material may be a single crystal or polycrystalline diamond. As used herein, the term RRQF means Relative Raman Quality factor. Raman spectroscopy, known to those skilled in the art, is a non-destructive spectroscopic technique which provides detailed information about the vibrational modes of the molecules under test through principal of inelastic scattering of photons, or Raman scattering, where molecular bond states exhibit a characteristic Raman shift at signature wavenumber. The diamond signature peak is known to be about 1332 cm⁻¹±2 cm⁻¹ within the so-called diamond band between about 1330 cm−1 to 1390 cm⁻¹ corresponding to the various sp³ bound states and known graphitic band between about 1400 cm⁻¹ to 1600 cm⁻¹, corresponding to the various sp² bound states. The intensity is normatively provided in counts of arbitrary units.

The inventor discovers that in the process of implementing the application: diamond, whether in single crystal, microcrystalline, or nanocrystalline form, shares the same fundamental building block of the carbon atom arranged in a tetrahedral lattice. The variations come in the form of grain boundaries, defects, and overall crystallinity. From a topological standpoint, it is considered that each form of diamond is a different “state” or manifestation of the same underlying material. Topologically, it is considered that the invariance in the molecular structure of carbon atoms in the diamond lattice across these different forms. While the macroscopic properties such as electrical conductivity, hardness, etc., change significantly between single-crystal and nanocrystalline diamond, the local bonding environment of each carbon atom remains tetrahedrally coordinated with four other carbons in a sp³ bond state arranged in variable geometric diamond structure. This is considered herein as a type of “local” topological invariance. In the case where sp³ bonding is maintained amongst two coordinated carbon atom molecular states, the so-called dimmer pairs seen in higher volumes in nanocrystalline (NCD) and ultrananocrystalline (UNCD) diamond volumes, the topological state is seen distinctly changed, where under UV Raman Spectroscopy the diamond signature peak is shifted in favor of the 1335 cm⁻¹ to 1390 cm⁻¹ region, and the intensity of contributions from the graphitic band are seen to correspondingly increase. This shows while the Raman spectroscopy technique can be quite sensitive to carbon bond states in the various diamond allotropes, techniques such as X-ray diffraction or XRD analysis, are less sensitive, as even UNCD materials can show primarily (111) predominance, masking the local geometric states amongst global orientations. The points in the proposed topological space then represent different states or conditions of the diamond material, characterized by their specific Raman signatures. Each point corresponds to a particular set of physical properties or structural characteristics of the diamond, such as grain size, crystallinity, and defect density. The neighborhoods of each point could be defined by variations in the Relative Raman Quality Factor, RRQF. For example, a neighborhood could consist of all diamond states that have Raman signatures within a certain range of RRQF. This captures the notion of “closeness” or similarity between different diamond states in terms of their Raman characteristics and related molecular properties. RRQF, as defined by the intensity and sharpness of the diamond Raman peak at 1332 cm⁻¹ (indicative of sp³ bonding) and its relation to any graphitic G-band features (indicative of sp² bonding), provides a measure of crystal quality and ordering. This factor can then serve as a boundary defining the extent of the neighborhoods. Whereas, in quantum optics the quality factor is known to be defined as the frequency divided by the Full Width Half Maximum about the frequency or QF=f/FWHM; Herein, we define RRQF specifically for a Raman Shift using UV Raman Spectroscopy: RRQF=(λ_{D}/FWHM_{D})·(I_{D}/I_{G}) where λ_{D} is the diamond signature peak (1332 cm⁻¹), FWHM_{D} is the Full width at half maximum of the diamond peak about the region 1330 to 1390 cm⁻¹ of the band, as used herein the terms I_{D} and I_{G} are defined as the Intensity of the diamond peak at 1332 cm⁻¹ and the Intensity about the graphitic band (G-band), respectively and both are measured normatively in counts or arbitrary units depending on the Raman spectroscopy system's calibration. Further wavelength is used in lieu of frequency for the convenience of producing terms that do not require exponents to denote. The ratio I_{D}/I_{G} is a dimensionless quantity as it's comparing the relative intensities of two spectral features. For example, a diamond peak 1332 cm⁻¹ with FWHM_{D} of not more than 20 cm⁻¹ and a I_{D}/I_{G} ratio of at least 2 yields the RRQF value of 133.2. Therefore, given that the RRQF is a ratio of these quantities, the ultimate units of RRQF itself are dimensionless, as it represents the product of a pure quality factor and a probability amplitude of diamond's structural integrity based on its Raman signature. The dimensionless nature makes it a versatile and comparative metric that can be used across a plurality of different samples and conditions. Therefore, a success of the disclosed approach, the presented disclosures can be promptly applied to the development of practical diamond based optical and electronic materials with any chemical composition and atom arrangement (i.e. single crystal, microcrystalline, nanocrystalline and ultra nanocrystalline diamond).

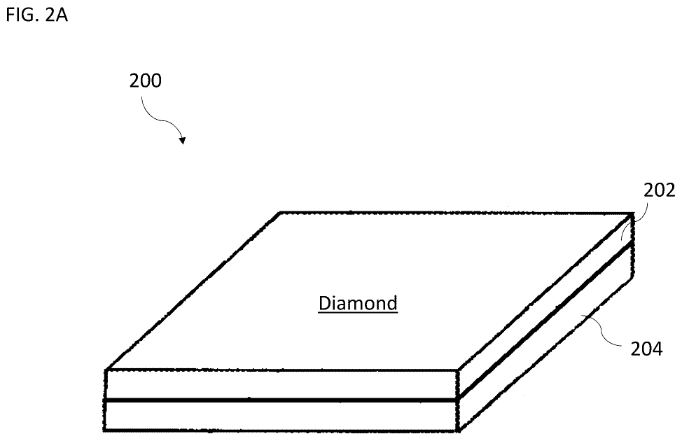

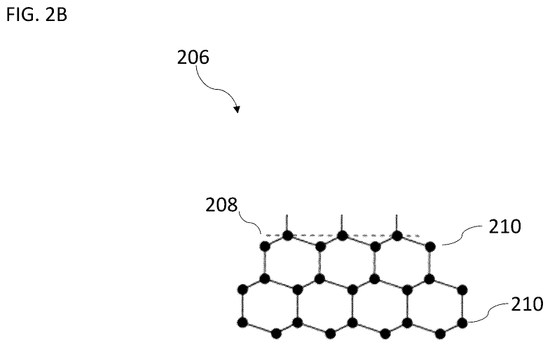

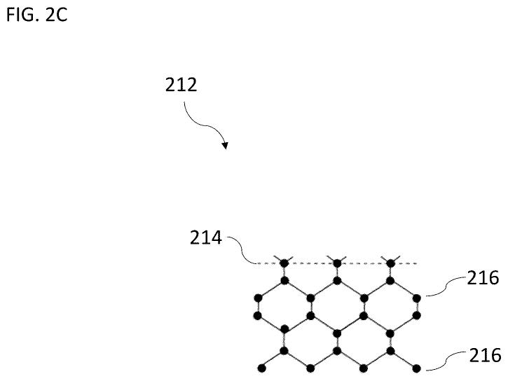

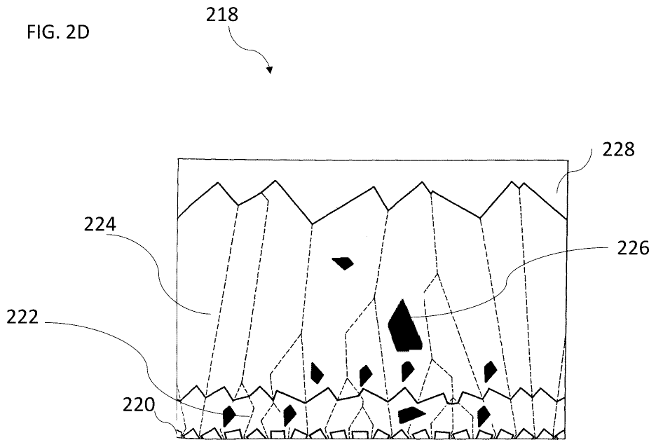

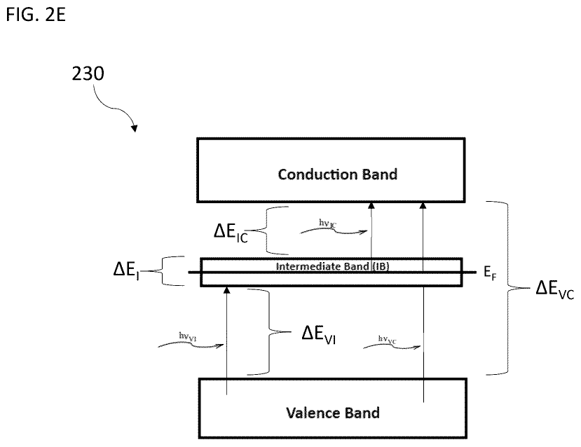

FIG. 2A is a perspective view of a prior art model of an intrinsic diamond wafer or plate upon which the method of FIG. 1 may be practiced. Though not limited to any diamond crystalline or grain size type, the material of method 100 is the intrinsic diamond wafer or plate 200. The intrinsic diamond wafer 200 may include a diamond layer 202, and a substrate layer 204. The Diamond layer 202 may be, but is not limited to, single crystal or polycrystalline. The substrate layer 204 may be but is not limited to HPHT Diamond, Iridium, Silicon, Silicon Carbide, Silicon Dioxide, Sapphire, and/or combinations thereof. The intrinsic diamond wafer or plate 200 may be 100 mm in diameter. The diamond layer 202 may be a 5 um single crystal diamond grown by Chemical Vapor Deposition method. The substrate layer 204 may be 500 um. The diamond layer 202 and substrate layers 204 may be continuous diamond grown by CVD or HPHT method and be plates of smaller dimension such as 5 mm×5 mm or 7 mm×7 mm s, such as the diamond materials available commercially from Element 6, Diamond Foundry, and DiamFab. The first step 102 of method 100 may include selecting a variety of diamond crystalline materials such as, but not limited to, the exemplary diamond layer 202 of intrinsic diamond wafer or plate 200.

FIG. 2B is an illustration of an intrinsic diamond lattice structure 206, which could be, but is not limited to, an intrinsic diamond lattice structure of diamond layer 202. FIG. 2B is known to those of skill in the art and is known to be an idealized view of the (111)-oriented plane from a side view perspective. The surface 208 is denoted with dashed line and contains within and below a plurality of carbon atoms 210. In the illustrated model, the intrinsic diamond lattice structure 206 is shown free of defects where all the atoms comprising the molecule are representative of sp3 bonded carbon atoms 210.

FIG. 2C is an illustration of an intrinsic diamond lattice structure 212, which could be, but is not limited to, an intrinsic diamond lattice structure of diamond layer 202. FIG. 2C is known to those of skill in the art and is known to be an idealized view of the (100)-oriented plane from a side view perspective. The surface 214 is denoted with dashed line and contains within and below a plurality of carbon atoms 216. In the illustrated model, the intrinsic diamond lattice structure 206 is shown free of defects, or defects less than the range of 0 to 5×10¹⁶ cm⁻³ where all the atoms comprising the molecule are representative of sp³ bonded carbon atoms 216.

FIG. 2D is an illustration of a section of intrinsic diamond molecular crystal structure 218 deposited by Chemical Vapor Deposition (CVD) method, which could be, but is not limited to, a section of intrinsic diamond wafer or plate 200. FIG. 2D is known to those of skill in the art to be of the likeness of a Philips-Van der DRIFT model for cubic crystal polycrystalline materials deposited by CVD method, whereby crystalline growth, such as diamond, is nucleated/initiated from fine or ultrafine size nanoseed layer 220 comprised of randomly oriented crystal nano-surfaces, and where it is known that crystalline growth will proceed under a principle of least time, whereby crystal growth survives most probabilistically by orienting in the most remote crystallographic point, perpendicular to the growth surface, typically the (111) direction 222 for cubic crystals such as diamond, until coalescence into a thin growth surface, thereafter surviving further most-probabilistically in the direction perpendicular to the growth surface, the (110) direction 224 for cubic crystals including diamond. It also known by those skilled in the art that CVD growth of diamond has a high density of vacancies incorporated during growth, which migrate toward one another and form complex vacancies chains, interstitial-vacancy defect complexes, which coalesce into void regions 226 incorporated within the diamond bulk volume. It is known regions 226 can correspond to a vacancy dislocation front, which could be crystal grain boundaries, and are known to be comprised of majority sp2 bound or mixed sp3/sp2 bond states within the molecular volume. Distinguishing amongst these molecular differences is accomplished in practice both non-destructively by the described Raman spectroscopy technique and via other destructive methods such as Transmission Electron Microscopy (TEM), Scanning Transmission Electron Microscopy ((S) TEM) and High-Resolution Transmission Electron Microscopy (HR-TEM). In the TEM techniques, the molecular structure can be directly imaged and is found to be in likeness to the molecular crystal structure 218, where differences in brightness correspond to density of electrons, and the void regions 226 appear darker in contrast to the surrounding sp-3 coordinated volume. Growth terminates rendering a surface 228, with geometric orientation reflecting mixed <111>, <110> and <100> oriented volume features.

The inventor discovers further that in the process of implementing the application: The ideal perfect single crystal diamond lattice, the naturally occurring so-called type IIa diamond contains within it a volume of vacancies that introduce localized states within the diamond electronic band gap, as physically evidenced via cathodoluminescence (CL) by the characteristic so-called Band-A luminescence at approximately 2.9 eV, or in the range of 2.13 eV to 3.13 eV above the conduction band, known to those skilled in the art to correspond to the neutral donor vacancy of the self-interstitial. Further, the Band-A luminescence is seen quenched either through annealing above temperatures of 420 degrees Celsius and/or through vacancy-interstitial defect formation in the presence of nearby interstitial dopants, and through dislocation front formations such as diamond grain boundaries. At sufficient density, the vacancy states begin to overlap to form “bands” of states situated at about 2.9 eV or in the range of 2.1 eV to 3.13eVabove the valence band, however, these are not the bands of the native diamond system, i.e. the conduction or valence bands, but rather instead, a dense collection of localized states within the band gap constituting a competing intermediate band. These states can trap charge carriers, altering the electronic and optical properties of the diamond. Furthermore, as vacancy defects exist with different charge states, these states mediate processes like non-radiative recombination as well as introduce new optically active transitions (e.g. N—V, Si—V, Ge—V centers in diamond). For example, some defects might act as donors, while others act as acceptors. The net effect on the electronic properties would depend on the relative concentrations and energy levels of these defects. Where the presence of vacancy related defects introduces trap states within the intrinsic diamond band gap, these trap states can be represented as: Eₜ=Eᵥ+Eₜᵣₐₚ, where Eₜ is defined as the energy of the trap state, Eᵥ is the energy of the valence band maximum, and Eₜᵣₐₚ is the energy of the defect state relative to the valence band maximum. For a semiconductor with defects, the density of states g(E) near the Fermi level (E_{F}) due to vacancies can be approximated as g(E)=g0(E)−Δg(E), where: g0(E) is defined as the density of states without defects and Δg(E)=Nvδ(E−Eₜᵣₐₚ), where Nv is defined as the density of vacancies, and δ(E−Eₜᵣₐₚ) is defined as the Dirac delta function representing the energy level introduced by the defect. The E−Eₜᵣₐₚ term is known where 5.47 eV-2.9 eV, and the Direct delta function is bounded by solutions between 0 and 1. Thus, at room temperature, either all intrinsic electron carriers within the host diamond lattice occupy the plurality of Eₜᵣₐₚ states as the lowest possible electron state corresponding to the conduction band, or by zero solution to the Dirac delta function, all trap states are quenched and the density of states is equivalent to those of the defect free system. Untreated, the intermediate band (IB) will fix the fermi level and the corresponding fermi surface to IB associated states, instead of lying halfway between the conduction and valence bands of the host diamond system at ambient pressures and temperatures. Further, even for donor-type defects sufficiently close to substitutional positions within the diamond lattice, but interstitially located, achieving full activation (i.e., every dopant atom contributing a free carrier) will remain a challenge, especially for n-type dopants. Untreated, the effective doping will be lower than the introduced dopant concentration. It is also known that at annealing temperatures above 420 C, neutral vacancy levels are quenched, whereby neutral interstitials have combined to form divacancies, amongst other complexes. As such, the temperatures normative to diamond growth via CVD and HPHT methods, and in-situ doping methods practiced therein, most probabilistically would yield the dopant states associated with the IB, and as such demonstrate low carrier mobilities, poor activation, etc. as seen by practical demonstrations of diamond semiconductor materials and devices heretofore. Therefore, another failing of the prior art, dopant experiments to date have shown varying degrees of vacancy-interstitial defect electronic contribution and not n-type doping of the diamond system. Furthermore, the term substituent dopant is used in place of substitutional dopant intentionally heretofore to distinguish between carrier states added through the replacement of a carbon atom and carrier states added through vacancy-defect complex created states associated with the intermediate band in the topological space.

FIG. 2E is a model of the intrinsic diamond electronic band gap 230, which could be, but is not limited to, the intrinsic diamond wafer or plate 200 and the diamond layer 202. The width of the band gap, ΔE_{VC} is known to be approximately 5.47 eV, and the energy difference between the valence band and bottom of the intermediate band, ΔE_{VI}, is approximately 2.9 eV. The Fermi level, E_{F}, is seen pinned by the presence of the intermediate band, and as such, the fermi surface is also affected in topological space. The intermediate band formed by the vacancy-interstitial complexes (self and dopant) is located between the filled diamond valence band and the empty diamond conduction band. The presence of the intermediate band created by the high concentration of vacancies or vacancy-impurities stick the fermi level (and fermi surface in topological space) at the intermediate band because of the high concentration of allowed states. The isolated neutral and charged vacancies (V0, V+, and V−) and the vacancy chains (V−− and V++) will have different formation energies as a function of the local fermi level. Vacancies and interstitial defects are mobile, where isolated vacancies will meet to form vacancy chains, and both isolated and chain vacancies will meet with defects to form vacancy-interstitial defect complexes, driven by the formation energy (dependent on the fermi level) and local crystalline geometry.

The second step 104 of method 100 may include introducing a minimal amount of interstitial dopant atoms to the diamond lattice to create interference with vacancy wavefront. The introduction of interstitial dopant atoms may disrupt or alter the usual propagation of these waves and may cause a diminution of the extended effects caused by vacancies and their propagation. The interstitial dopant may be but is not limited to lithium, sodium, and hydrogen. The minimal amount of interstitial atoms of second step 104 may be for example, but is not limited to, approximately 1×10⁸ cm⁻² of lithium. In other embodiments, the minimal amount of interstitial dopant atoms of second step 104 may be for example, but is not limited to, approximately 1×10⁹ cm⁻² of lithium, and a range of 1×10⁸ cm⁻² to 1×10¹⁰ cm⁻² where the thickness of the co-doped diamond is generally 0.5 um to 5.0 um. Second step 104 may be accomplished by interstitial co-doping at extremely low to room temperatures in that interstitial defects and vacancies may be limitedly mobile, but lithium may take interstitial positioning. The second step 104 may create mobile vacancies for subsequent dopants, in addition to some substitutional positioning through the vacancies created by self-interstitials displaced by the impinging ion.

The third step 106 of method 100 may include introducing a minimal amount in the range of 1×10⁸ cm⁻² to 1×10¹¹ cm⁻², of substituent acceptor strain dopant atoms. The substituent dopant atoms may be introduced to the diamond lattice through the ion tracks created by step 104. For example, third step 106 may include introducing smaller substituent dopant atoms using ion implantation at energies less than 1 MeV to minimize localized self-annealing effects and maintain precise layer control within the topological space. The smaller co-dopant may introduce biaxial strain, which may be more easily accommodated in the through reorientation of the local geometries, such as for example the <100> orientation. The acceptor substituent dopant may be, but is not limited to, Boron or Aluminum. The minimal amount of interstitial atoms of third step 106 may be for example, but is not limited to, approximately 1×10⁸ cm⁻² of boron. In other embodiments, the minimal amount of interstitial dopant atoms of third step 106 may be for example, but is not limited to, approximately 1×10⁹ cm⁻² of boron, and a range of 1×10⁸ cm⁻² to 5×10¹⁰ cm⁻² where the thickness of the co-doped diamond is generally 0.5 um to 5.0 um. Third step 106 may be accomplished by interstitial co-doping at extremely low to room temperatures in that interstitial defects and vacancies may be limitedly mobile, but boron may take both substituent and interstitial positioning. The third step 106 may create mobile vacancies for subsequent dopants, in addition to some substitutional positioning through the vacancies created by self-interstitials displaced by the impinging ion.

In the fourth step, 108, a plurality of substituent donor dopant atoms is introduced. The as-implanted diamond topological space with local vacancy wavefront interference and/or diffraction, and the biaxial system stress induced in the lattice from second step 104 and third step 106, facilitates the introduction of donor dopants into near substituent positioning. The substituent donor dopant may be for example but is not limited to Phosphorous, Nitrogen, Sulfur, and Oxygen. Donor atoms will have at least one more or more valence electrons than carbon, which perturb the electronic structure. Where the plurality of substituent donor dopant atoms exceeds the minimized concentration of remaining unquenched vacancy states about the topological space, and where the sp³ bonding in diamond allows for angular momentum conservation through bond reorientation, the introduction of further donor dopants must be accompanied by a localized reorientation, in accordance with the least time principles of crystalline growth mentioned in the preceding section. For example, for (111) or (110) surface, reorientation about the (100) plane might offer more favorable bonding configurations that minimize energy and preserve angular momentum when accommodating both P and the smaller co-dopant, where the (111) inter planer distances are known to be 0.206 nm and where the (100) inter planer distances are known to be about 0.356 nm, the (100) plane would be the most remote point perpendicular to both (111) and (110) surfaces. The effective reduction or elimination of voids is also attributed, in part, to the more consistent growth direction. A consistent growth direction can lead to a more compact and regular arrangement of atoms, reducing the likelihood of voids or defects. Furthermore, as the surface reconstruction changes the <111> or <110> surface to <100>, the volume becomes further compacted.

In one embodiment, the ion implantation of step 108 may be performed using Phosphorus at or below approximately 0 degrees Celsius to impede vacancy and interstitial diffusion out of target layers, preserving depth controls afforded by the technique.

An embodiment of the application uses ion implantation of step 108 with tilt angles greater than 6 degrees in the implantation step 108, where underestimation of implantation depth in known to occur due to channeling of dopants in ion implantation of crystalline materials. Channeling is a known issue to those skilled in the art, and where the critical angle for a given ion dopant is known to be a function of ion implant mass and lattice constant parameters, and where said parameter is known for single crystal diamond to be approximately 0.3567 nm for the (100) oriented diamond and approximately 0.206 nm for the (111) oriented diamond diffraction planes. Doping may be performed on a Varian Ion Implantation System with a phosphorus mass 31 singly ionized dopant (i.e., 31P+).

An embodiment of the application provides a substituent doped diamond, the lattice structure of doped diamond comprises a plurality of carbon atoms, a lithium atom, a boron atom, and a plurality of phosphorus atoms, and a plurality of vacancies, with concentration of donor atoms at least 0.000568% of the diamond volume per cubic centimeter, which in the present embodiment is principally phosphorous, provide conduction electrons having ionization energies less than 0.31 eV.

An embodiment of the application provides ion implantation where the target species are doped molecularly instead of as individual ions, such as for example but not limited to, dopant adenine, C5N4Hn, the molecular ion will dissociate immediately at the surface into atomic components, entering the volume with equal velocities. The stopping depth would therefore be determined by implant mass energies, and as such, depth control may still be accomplished with fewer total doping steps. The molecule larger size however will generate more vacancies per ion than single ion doping sequentially and may generate an increase in wanted defects incorporated.

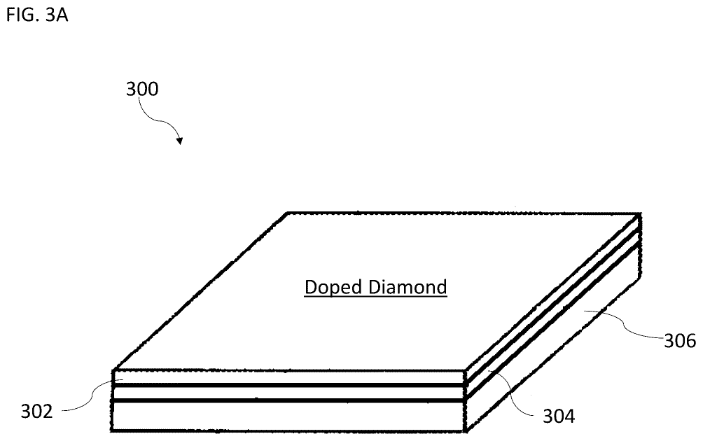

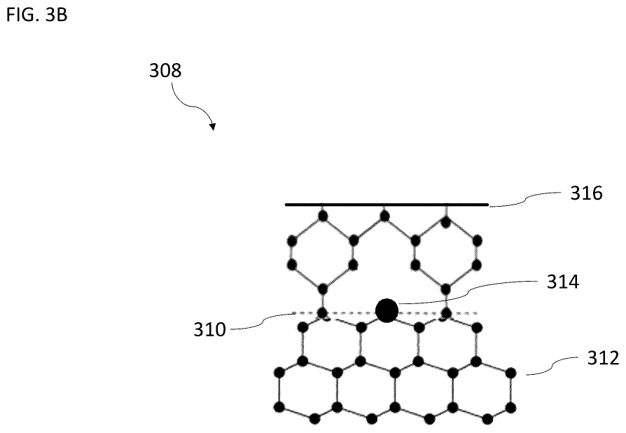

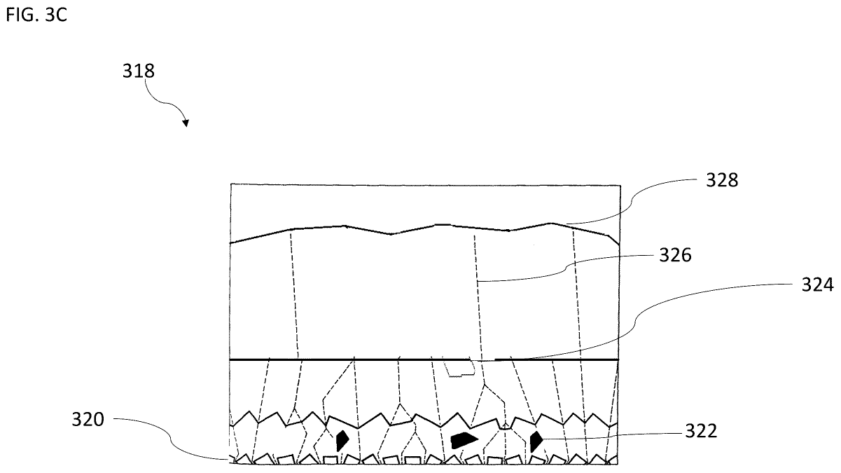

FIG. 3A is a perspective view of a model of a doped diamond wafer or plate 300, such as may be fabricated by subjecting the intrinsic diamond wafer or plate 200 to method 100. The doped diamond wafer or plate 300 may include a doped layer 302, an intrinsic or unintentionally doped diamond layer 304, and a substrate layer 306.

FIG. 3B is an illustration of a substituent doped diamond lattice structure 308, such as may be fabricated by subjecting the intrinsic diamond lattice structure of 206 to method 100. The native (111) diamond lattice structure original surface 310 with neighboring carbon atoms 312 is seen reoriented by the successful introduction of nearby larger substituent dopant 314 into the lattice structure 308, where the regrown surface volume 316 now shows characteristic (100) orientation. In practice, this may be directly imaged by such high-resolution techniques such as Transmission Electron Microscopy (TEM) and from top view perspective with Scanning Electron Microscopy (SEM), at the appropriate imaging scales.

FIG. 3C is an illustration of a section of substituent doped diamond molecular crystal structure 318, such as may be fabricated by subjecting the intrinsic diamond molecular crystal structure of 218 to method 100. Compared to the intrinsic diamond molecular crystal structure 218, the modified overall structure, including the deepest depth undoped region 320, shows a characteristic reduction or absence of void regions 322. Above the undoped/doped region boundary 324, the volume is seen to be densely packed in the reoriented volume, where orientation 326 is visibly changed from the intrinsic state and where consistent growth direction leads to a more compact and regular arrangement of atoms, reducing the likelihood of voids. The modified substituent doped surface 328 is also changed from intrinsic crystal structure 218, where the surface angles will show compaction to (100) coordinated planes, and where such volume reduction, crystalline diffraction and electron density changes be seen directly via techniques such as TEM, (S) TEM, and HR-TEM, and where the brightness contrasts are known to be due to differences in electron density in the volume.

The inventor discovers further still that in the process of implementing the application: substituent dopant atoms may be placed close to neutral vacancies with topological break to local crystal symmetry about the reoriented volume, but can only be stabilized once formed, and will otherwise diffuse out of the doped region to equalize charge balances and arrange in lowest rest energy configurations in the volume. Given sufficient energy or time, the doping profiles immediately following the implantation steps will substantially change. Due to the large energy difference between the top of the lowest conduction band state (approximately 2.9 eV above the valence band) and the conduction band minimum, the prior art fails to provide sufficient pathway to electronic activation of the substituent dopants, where using the annealing approaches implemented to date, that is in-situ CVD and HPHT, oven annealing and rapid thermal annealing, thermal energy is provided to a plurality of vacancy related defects, and the high temperatures utilized favor vacancy-defect complex formation over substitutional donor complex formation, even at short duration. Therefore, optical annealing methods such as pulsed laser irradiation may be utilized to provide sufficient energies to drive dopant electronic activation and recrystallization of the damaged implant layers, however sufficient optical energy should be provided such that vacancy defect mechanisms are suppressed in favor of dopant-vacancy annihilation. With sufficient plurality of electrons transferred from IB states to conduction band and from conduction band minimums to created substituent dopant states, substituent dopant centers will remain relatively undisturbed, where orbitals and the spin states' coherence is protected by the symmetries and topological characteristics of the diamond lattice, making them less susceptible to decoherence mechanisms.

The fifth step 110 of method 100, may include subjecting the diamond lattice to pulsed laser irradiation. The pulsed laser irradiation may be done using laser wavelength of 532 nm, which may be generated by a Q-switched, frequency doubled Nd-YAG laser, and beam energy density of less than 50 Joules/cm2. Pulsed laser irradiation may drive volume compaction through annihilation of vacancy and defect and increased crystalline ordering, and as such may restore integrity to portions of the diamond lattice that may have been damaged during the second step 104, the third step 106, and the fourth step 108 and may electrically activate the dopant substituent atoms. Successive increase to beam energy density with successive pulses may be beneficial as the pulsed laser irradiation drives improved crystal quality through recombination and improved ordering and as such there is ever improving thermal energy dissipation in the system. Further, pulse times in excess of the excitation-relaxation lifetimes, known to be approximately 1.1 ns at room temperature, may be beneficial to drive vacancy-donor conversion efficiencies. The pulsed laser irradiation step 110 may be done in open air and at ambient temperatures and pressures.

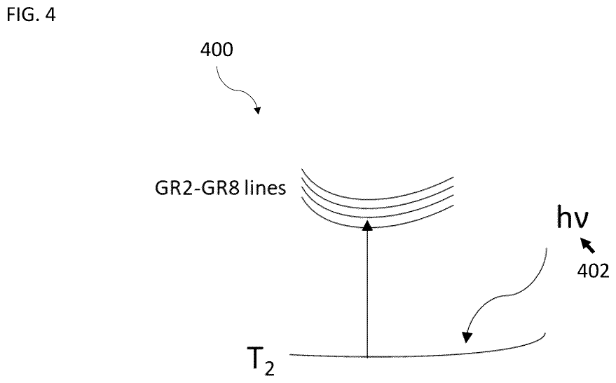

FIG. 4 is an energy level diagram of the diamond band gap 400. FIG. 4A is known to those of skill in the art to be the energy level diagram corresponding to the neutral monovacancy in diamond. The input energy 402 may excite electrons from the lowest conduction band excitation state T2 into higher energy conduction band states, such as may be the result of subjecting the doped diamond structure of fourth step 108 to the pulsed laser irradiation of fifth step 110 in method 100. The electronically activated doped diamond may include a plurality of carbon atoms, a plurality of phosphorous atoms, a plurality of vacancies, a boron atom, and a lithium atom.

Another embodiment of the application uses wavelengths of 193 nm, such as generated by ArF excimer laser, energy densities less than 50 Joules/cm2, and pulse times less than 100 ns, such that energy provided to the system implanted by method 100 is greater than the band gap energy 5.47 eV, and where compaction can be accelerated to form ultra-high crystallinity without deleterious effects to substituent doping.

Another embodiment of the application uses wavelengths greater than 550 nm, such that energy can be provided to form stable quantum optical defect centers in a surrounding high-crystalline quality system, providing long coherence times in excess of 220 us.

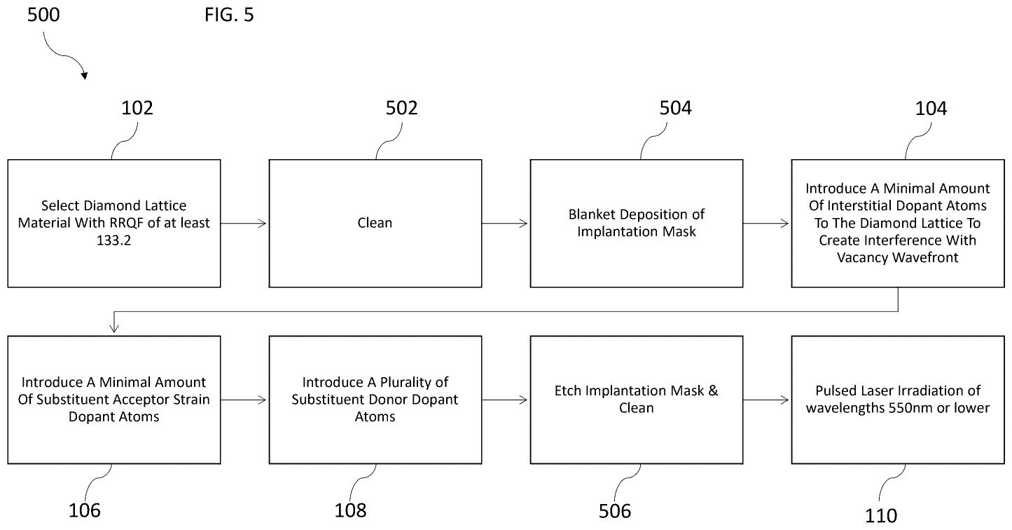

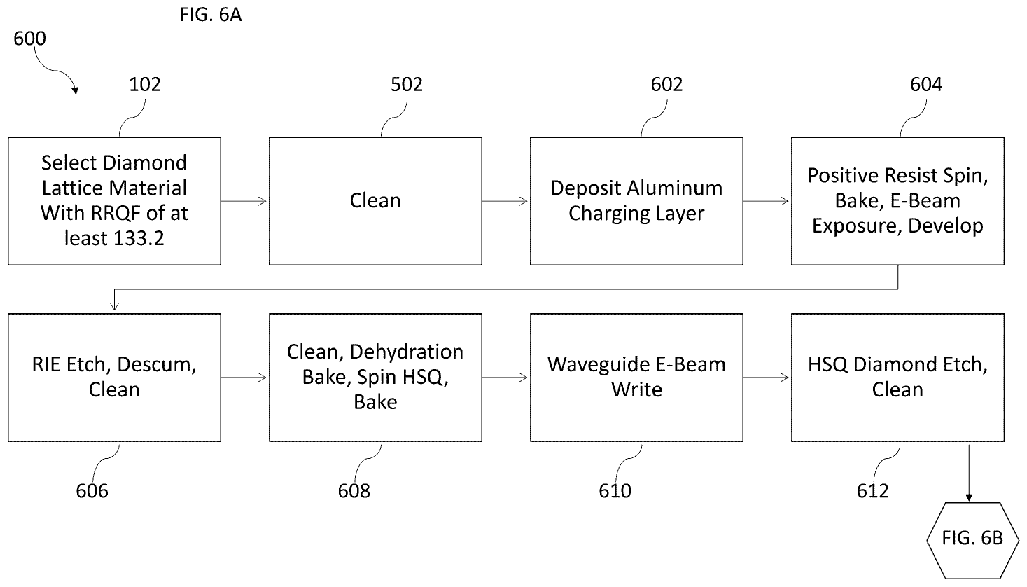

FIG. 5 shows a block diagram of a second embodiment of the method 500 for fabricating doped layers within diamond material. The first step of method 500 may be the same as the first step 102 of method 100, which includes selecting diamond lattice material with RRQF of at least 133.2. The second step 502 of method 500 may include cleaning the diamond material to remove organic and ionic contaminants from the surface volume. For example, second step 502 may include cleaning the intrinsic diamond wafer or plate 200. The cleaning may be an aggressive corrosive clean, for example but not limited to, an RCA clean, known to those with skill in the art. One example of such an RCA clean includes: applying 5 parts of deionized water: 1 part ammonium hydroxide (29% by weight of NH3): 1 part H₂O₂ (hydrogen peroxide, 30%) for 10 minutes at 85 degrees Celsius; applying 100:1 DI:HF solution for 20 seconds; applying a solution of 6 parts of deionized water: 1 part hydrochloric acid (37% by weight): 1 part H₂O₂ (hydrogen peroxide, 30%) for 10 minutes at 85 degrees Celsius; then applying standard DI water and drying techniques. The third step 504 of method 500 may include blanket deposition of implantation mask, where the mask may act as a protective surface for subsequent ballistic doping steps. Mask materials may include but are not limited to commercial photoresists or refractory metals such as aluminum or titanium. For example, the mask deposition may be accomplished by physical vapor deposition (PVD) sputter technique utilizing a Kurt J Lesker Sputter system, where Aluminum sputter target is deposited using 200 watts DC power at 5 mTorr pressure under 50 sccm of flowing Argon for 226 seconds, yielding approximately 30 nm of Al thickness. The fourth step of method 500 may be the same as the second step 104 of method 100, which includes introducing a minimal amount of interstitial dopant atoms to the diamond lattice to create interference with vacancy wavefront. The fifth step of method 500 may be the same as the third step 106 of method 100, which includes introducing a minimal amount of substituent acceptor strain dopant atoms. The sixth step of method 500 may be the same as the fourth step 108 of method 100, which includes introducing a plurality of substituent donor dopant atoms. The seventh step 506 of method 500, which includes etching implantation mask and cleaning, may include the use of standard Aluminum wet etchant mixtures, known to those skilled in the art to be a solution of 16:1:1:2 of Phosphoric Acid, Nitric Acid, Acetic Acid and deionized water. The step may also include but is not limited to, using standard acid cleans such as Piranha solution, known to those with skill in the art to be a solution of 3:1 mixture of sulfuric acid and 30% hydrogen peroxide. The eighth step of method 500 may be the same as the fifth step 110 of method 100, which includes pulsed laser irradiation of wavelengths 550 nm or lower.

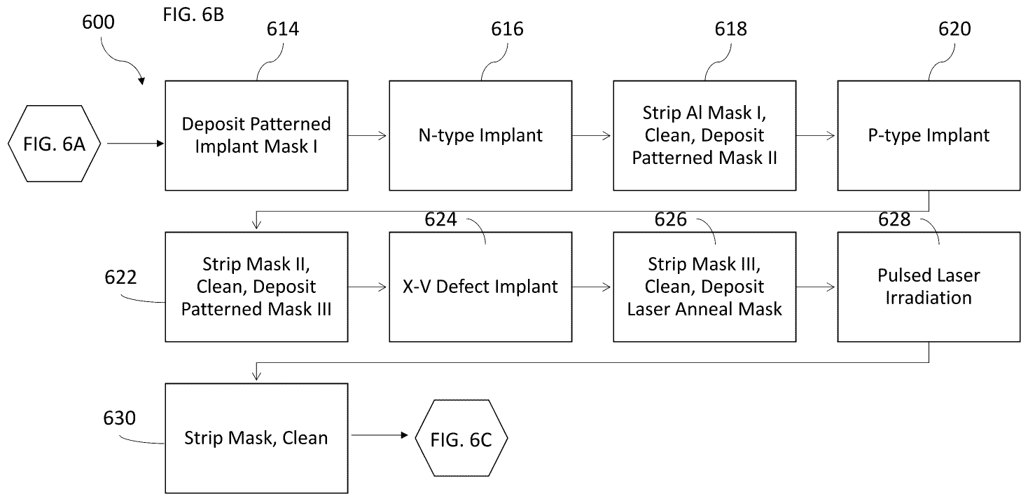

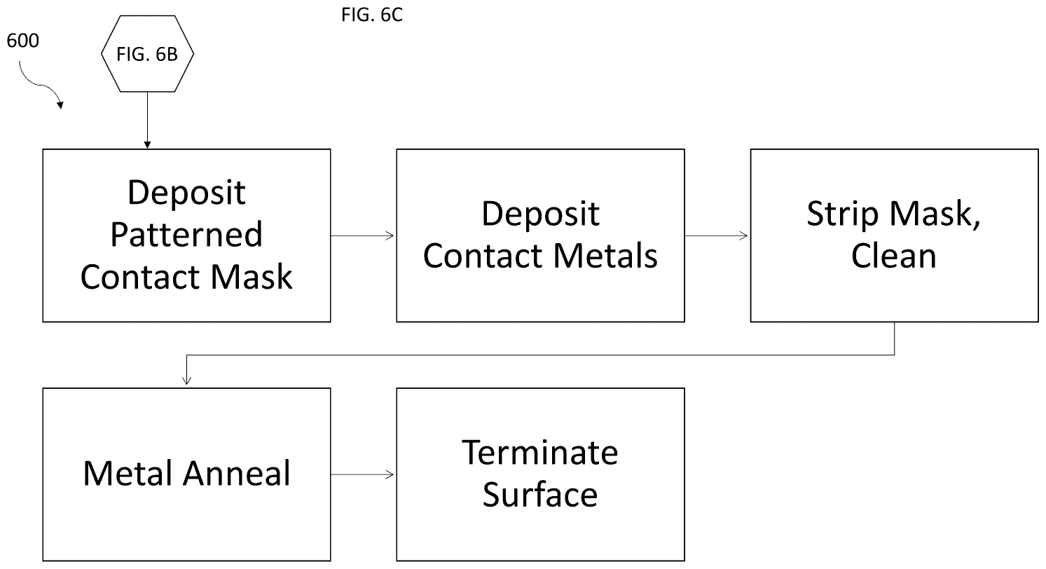

For some applications it may be advantageous to degenerately and/or differentially dope different parts of the same diamond wafer, for example, to create n-type (n) and heavily doped n-type (n+), and/or p-type (p) and heavily doped p-type (p+) regions. In embodiments, various semiconductor and quantum photonic devices are created including p-n and p-i-n junction phase shifters, and ring-resonator qubit pair sources. FIG. 6A, FIG. 6B and FIG. 6C show a block diagram of a third embodiment of the method 600 for fabricating doped layers within diamond materials. Method 600 provides for a process for fabricating n-type, p-type, and optical defect within diamond semiconductors for a monolithically integrated quantum photonic modulator device. The first step of method 600 may be the same as the first step 102 of method 100, which includes selecting diamond lattice material with RRQF of at least 133.2.

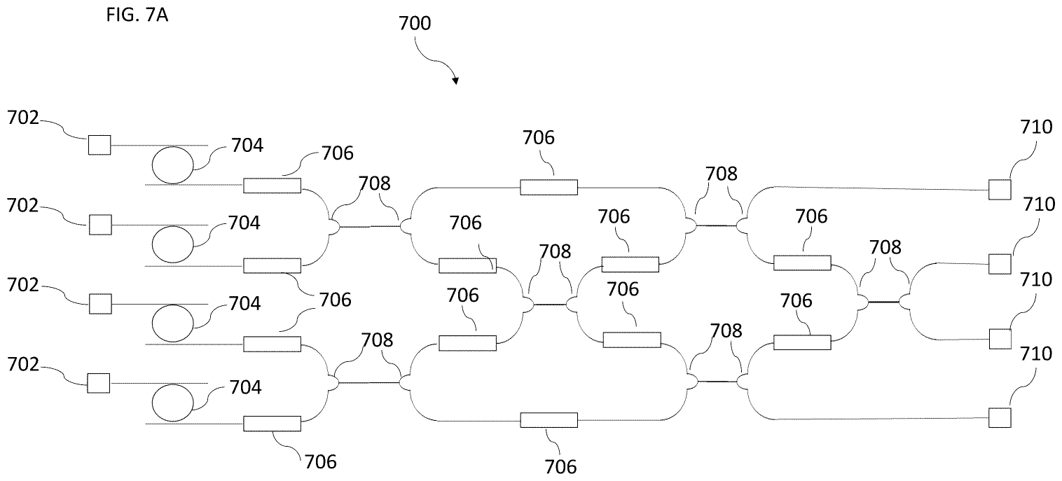

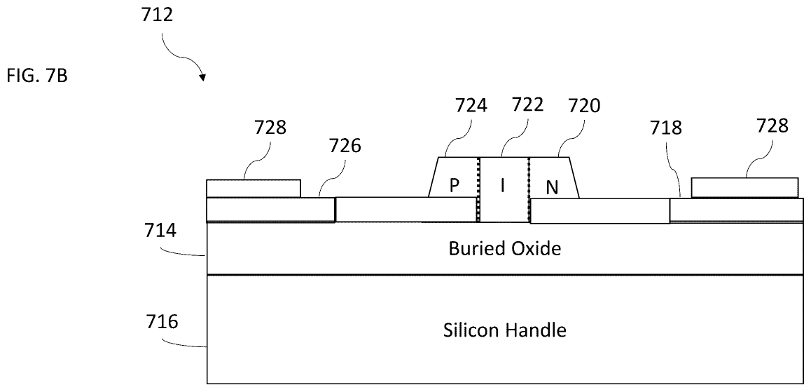

FIG. 7A shows a top view of an exemplary model of an integrated quantum photonic modulator device 700 that may be fabricated according to the method 600. Integrated quantum photonic modulator device 700 may include an intrinsic diamond region, which may be the intrinsic diamond wafer or plate material of 200, in the form of waveguide grating couplers 702 and 710, and waveguide beam splitters 708, sandwiched around a ring-resonator qubit source region 704 and a series of p-i-n junction phase shifters 706.

FIG. 7B. shows a side view of an exemplary model of a p-i-n phase shifter 712, which may be the P-i-n phase shifter 706 of integrated quantum photonic modulator device 700, that may be fabricated according to the method 600. The p-i-n phase shifter 712 may include unintentionally doped semiconductor region 722, with approximate width of 200 nm and thickness of 500 nm, sandwiched between an n-type semiconductor region 720 with approximate width of 225 nm and thickness of 500 nm, and a p-type semiconductor 724 with approximate width of 225 nm and width of 500 nm. The method 600 may be paired with computer software SRIM 2008 for accurate depth control with respect different implantation species and beam energies, with software inputs corresponding to the diamond system: density of 3.515, displacement energy of 45 eV, lattice binding energy of 3 eV, and surface binding energy of 7.41 eV. FIG. 7B also shows metallic contact/bonding pads 728 for connecting to the n⁻-type semiconductor or semimetal region 718 of approximate thickness 200 nm, and the p⁺-type semiconductor or semimetal region 726 with approximate thickness of 200 nm.

The second step of method 600 may be the same as the second step 502 of method 500, including cleaning the diamond surface volume to remove organic and ionic contaminants. The third step 602 of method 600, which includes depositing an aluminum charging layer, may be accomplished by physical vapor deposition (PVD) sputter technique utilizing a Kurt J Lesker Sputter system, where Aluminum sputter target is deposited using 200 watts DC power at 5 mTorr pressure under 50 sccm of flowing Argon for 113 seconds, yielding approximately 15 nm of Al thickness. The fourth step 604 of method 600 includes a positive resist spin, bake, E-Beam exposure, and development. The resist may be, but is not limited to, commercially available 495 PMMA A resist. The resist may be applied after a pre-bake for one minute at 180 degrees Celsius, coating 200 nm thickness using a spin speed of 2500 rpm, and a post-spin bake at temperatures between 100 and 180 degrees Celsius for 70 seconds. E-beam exposure may be done using standard e-beam lithography systems such as made by RAITH, using a mask file comprising cross-hatch alignment structures or the like, and may implement 500 um by 500 um write fields at 0.02 um resolution, and beam energy of 2 kV with beam area dose of 375 uC/cm. Post-e-beam exposure, development may be accomplished using known PMMA developer mixture of 1:3 MIBK to Isopropyl alcohol. The fifth step 606 of method 600, which includes RIE etch, descum, and clean, may comprise reactive ion etching which may be practiced using commercial systems such as those manufactured by oxford systems, and where using input parameters such as 300 W forward power, 0V DC bias, 50:1 ratio of 02 to Argon gas sources at 9 mTorr base pressure, etching raters of approximately 40 nm/min may be controllably achieved to the target depth thickness. Descum process, which is known to those of skill in the art, may be achieved using standard dry recipes on commercially available ozone generator systems, such as those manufactured by MKS. The Cleaning step may be the cleaning step 502 of method 500. The sixth step 608 of method 600, which includes clean, dehydration bake, spin HSQ, and bake may include exposing the alignment patterned diamond material of 600 to cleaning with Toluene, Acetone, IPA, and DI water for 2 minutes each, followed by a dehydration bake on a hotplate for 5 minutes at 120 degrees Celsius. HSQ may be spun using a 1 mL pipette to extract 0.75 mL of HSQ and deposited while in spinning, 6% at 1000 RPM for 60 seconds, with 500 RPM ramp up and ramp down before achieving target spin speed, then exposing to hot plate surface at 120 degrees Celsius for 2 minutes, and letting cool down before proceeding. In the seventh step 610 of method 100, which includes waveguide E-Beam write, may include using the e-beam system of the fourth step 604 with a mask file comprising of the structures of integrated quantum photonic modulator device system 700. Where it is known beam area dose of approximately 3000 uC/cm2 is effective for diamond, 2700 uc/cm2 may be utilized to not overexpose in the case of polycrystalline diamond systems with corresponding resolutions of 0.001 μm and beam energy of 10 kV and probe current of approximately 10 nA. In the eight step 612, which includes HSQ Diamond Etch and Clean, post e-beam exposure of the previous step, the material may be developed using commercially available developers containing TMAH such as MF CD-26, which may be heated to 60 degrees Celsius for uniform and timely development. The exposed pattern may be etched similarly to the RIE diamond etch step of 606, adjusting time scales to achieve the target etch dept of 300 nm. Clean steps include removal of remaining HSQ materials and the clean steps of 502 of method 500. Quick removal of HSQ is known to occur with ten second dip in buffered oxide etchant (50:1).

The ninth step 614 of method 600, which includes deposition of patterned implant mask I, which may include the previous steps of fourth step 604 of method 600, utilizing a pattern for n-type region openings in lieu of alignment marks, followed by the deposition of aluminum in the likeness of the third step 602, followed by the next step similar to step 606 of method 600, omitting the etch portion and utilizing descum and appropriate clean, followed by a next step of blanket Aluminum deposition in the likeness of the third step 602, such that portions to be n-type implanted will have differential Al mask thickness of about 30 nm and that elsewhere the thickness of Al will fully block dopants from reaching the diamond surface.

The tenth step 616 of method 600, which includes n-type implantation, may be the same as fourth step 104, fifth step 106, and sixth step 108 of method 500, modifying the dopant dose of phosphorous to 1×1012 cm⁻² to achieve target dopant concentration of approximately 1×1020 cm⁻³ at the desired depth. The eleventh step 618 of method 600 includes strip Al mask I, clean, deposit patterned mask II, which may be the same as the Al etchant seventh step 506 of method 500, and where clean and deposit patterned mask II may repeat the cleaning step 502 of method 500 and the ninth step 614 of method 600, changing the pattern file corresponding to p-type region opens. The twelfth step 620 of method 600 includes p-type implant, which may be the same as fourth step 104, fifth step 106, and sixth step 108 of method 500, modifying the dopant type and dose of fifth step 106 to be minimal substituent donor Nitrogen at 1×10⁹ cm⁻², and modifying the dopant type and dose of sixth step 108 to be plurality of substituent acceptor Boron at 1×1012 cm⁻² corresponding to target Boron concentration of 1×1020 cm⁻³ in the diamond volume at the target dept. The thirteenth step 622 of method 600 includes strip mask II, clean, deposit patterned mask III, which may be the same as eleventh step 618 of method 600, changing the pattern file corresponding to openings for the ring-resonator 704 region instead. The fourteenth step 624 of method 600 includes X-V Defect Implant, where X denotes one of the optical defect center generating dopant species such as Nitrogen, Silicon, Germanium amongst potentially others. In the present embodiment, Nitrogen is used, though the same principles and techniques may be practiced with Silicon and Germanium adjusting excitation energy to correspond to those optical centers. The methodology may be the same as the as fourth step 104, fifth step 106, and sixth step 108 of method 500, where the modified goal of creating quantum optical defect centers in lieu of substituent dopants. In the present embodiment steps 104-106 are combine by use of ion implantation of molecular dopant adenine, C5N4Hn, where interstitial defect H, strain dopant C, and optical donor N dope the system, but where strain dopant C can combine with neutral and singly charged vacancies, and where Nitrogen can form complexes but not preferentially occupy substitutional sites after doping. Using ion beam energy of approximately 70 keV, a dose of approximately 1×10⁹ cm⁻², and ion beam tilt angle greater than 6 degrees, a uniform doping layer may be achieved sub-surface within the ring-resonator structure 704.

The fifteenth step 626 of method 600 includes strip mask III, clean, deposit laser irradiation mask, and may be the same as eleventh step 618 of method 600, changing the pattern file corresponding to openings for the ring-resonator region 704, n-type doping region 718 and p-type region 726 instead. The sixteenth step 628 of method 600 includes pulsed laser irradiation and may be the same as eight step 110 of method 500. The n-type and p-type regions may be activated using laser wavelength corresponding to the 532 nm transition discussed. Further, as ring-resonator structure 704 calls for quantum defect activation, laser wavelength of 658 nm or 741 nm may be used, where it is known to those skilled in the art such wavelengths correspond to excitation and relaxation between the T2 lowest excited state of conduction band and A2, T1, and E the split off bands and ground states, respectively. Laser power levels may be maintained as previous, adjusting only for change to wavelength and pulse durations. The seventeenth step 630 of method 600 includes strip mask and clean, and may be the same as the seventh step 506 of method 500. The eighteenth step 632 of method 600 includes deposit patterned contact mask, which may include the previous steps of fourth step 604 of method 600, utilizing a mask file pattern for the contact metal opening 728, followed by the deposition of first Titanium (Ti) and next gold (Au). Deposition may be done by PVD method such as on Lesker Sputter systems, where 5 nm of Ti can be deposited using 200 W power, 50 sccm flowing Argon at 4 mTorr chamber pressure for approximately 50 seconds, and where 50 nm of Au can be deposited using 150 W DC Power under 50 sccm of flowing Argon at chamber pressure of 4 mTorr for approximately 180 seconds. The nineteenth step 634 of method 600 includes strip mask and clean steps, and may be the same as the descum and appropriate clean steps of the ninth step 614 of method 600. The twentieth step 636 of method 600 includes metal annealing, which may be accomplished in typical annealing furnaces. The metal furnace annealing may be performed at 350 degrees Celsius for two hours and may include annealing under a forming gas such as H2:Ar, and may be plasma assisted. The twenty-first step 638 of method 600 includes terminating the surface. There are few successful termination schemes for diamond, as known to those of skill in the art, where surface terminations may induce loss of conduction and graphitization at surface sites. The present application produces a stable defect surface, where negative electron affinity may be achieved with appropriate termination scheme. Therefore, the use of hydrogen termination, oxygen termination and hydroxyl termination may be practiced where hydrogen termination may be accomplished under atomic hydrogen producing conditions, oxygen termination may be accomplished by acid exposure followed by ozone treatment, and hydroxy termination may be accomplished by water vapor source exposure during hydrogen termination treatment.

The above descriptions of the disclosed embodiments are provided to enable persons skilled in the art to make, practice or use that which is defined in the application. Other embodiments and modifications will readily occur to those of ordinary skill in the art in view of these teachings without a further inventive step.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while steps are presented in a given order, alternative embodiments may perform routines having steps in a different order. The teachings of the invention provided herein can be applied to other systems, not only the systems described herein. The various embodiments described herein can be combined to provide further embodiments. These and other changes can be made to the invention in light of the detailed description.

All the above references and U.S. patents and applications are incorporated herein by reference. Aspects of the invention can be modified, if necessary, to employ the systems, functions and concepts of the various patents and applications described above to provide yet further embodiments of the invention.

These and other changes can be made to the invention in light of the above detailed description. In general, the terms used in the following claims, should not be construed to limit the invention to the specific embodiments disclosed in the specification, unless the above detailed description explicitly defines such terms. Accordingly, the actual scope of the invention encompasses the disclosed embodiments and all equivalent ways of practicing or implementing the invention under the claims.

While certain aspects of the invention are presented below in certain claim forms, the inventors contemplate the various aspects of the invention in any number of claim forms.

1. A method for co-doping a diamond material to enhance its electronic properties, comprising the steps of:
a) applying a protective mask over the surface of the diamond material, wherein the protective mask is selected from the group comprising: metals, photoresist, and other materials suitable for protecting the diamond surface and controlling ion implantation depth as a function of the mask material, thickness, ion type, level of ionization, and beam energy being selected to optimize the implantation depth and distribution of dopants within the diamond material;
b) Ion implanting
i. a first dopant species selected from the group comprising lithium (Li), sodium (Na), potassium (K), and the like into the diamond material through the protective mask, the diamond material being selected from the group comprising of single crystal diamond, microcrystalline diamond, nanocrystalline diamond, and ultrananocrystalline diamond, wherein the first implantation is designed to selectively scatter/reduce/eliminate intermediate band state effects and corresponding effects within the diamond structure;
ii. Ion implanting a second dopant species selected from the group comprising boron (B), aluminum (Al), gallium (Ga), and similar elements into the diamond material at a different energy and/or fluence level than the first dopant species, such that the second implantation introduces axial strain into the diamond lattice;
iii. Ion implanting a third dopant species selected from the group comprising phosphorus (P), nitrogen (N), oxygen (O), sulfur(S), and similar elements into the diamond material, wherein the third implantation is performed at a temperature less than 100 Kelvin to induce axial strain in a complementary axial direction; the implantation conditions designed to freeze carriers in probabilistically favorable occupancy, thereby reducing the formation of impurity states and enhancing the interaction between the conduction band and intermediate band states.

2. The method of claim 1, further comprising the step of annealing the co-doped diamond material using thermal annealing and/or pulsed laser annealing, wherein:
the thermal annealing is performed at a temperature sufficient to activate substituent dopants by aligning charge transfer mechanisms between the acceptor states with the valence band minimum and/or donor states with the conduction band minimum, is in excess of 400 C;
the pulsed laser annealing is performed using laser wavelengths between 500 and 550 nm to activate donor states by aligning charge transfer mechanisms with conduction band edge states, thereby optimizing carrier concentration and mobility within the diamond material and stabilizing the band states in preference to forming impurity localized states; wherein the laser pulse duration is less than 30 nanoseconds, and the laser energy density is less than 100 J/cm².

3. The method of claim 1, wherein the protective mask thickness, ion type, ionization level, and beam energy are optimized to achieve a specific depth profile for the dopants, ensuring that the dopant distribution is tailored to create a desired potential landscape within the diamond material.

4. The method of claim 1, wherein the diamond material is selected from the group comprising type IIa single crystal diamond, type IIb single crystal diamond, microcrystalline, nanocrystalline and other diamond types, with the co-doping process designed to modify the electronic properties by stabilizing substituent band states or eliminating corresponding intermediate band states within the diamond's band gap, leading to enhanced charge transport, increased carrier mobility, and tailored electronic band structures.

5. The method of claim 1, further including the step wherein the first dopant species is selected to scatter or neutralize vacancy or defect states within the diamond, the second dopant species is selected to introduce strain along specific crystallographic axes, modifying the lattice parameters to enhance or reduce specific electronic interactions; the third dopant species is selected to further tune the interaction between the conduction band and the introduced intermediate band states, optimizing the diamond material for specific electronic applications.

6. The method of claim 1 further including the step of wherein the Li+ implantation is achieved by the accelerated 7LI+ ions using a beam energy in the range of 5 to 1000 keV to a total level less than 10²² cm³ at room temperature, the B+ implantation is achieved by the accelerated 11B+ ions using a beam energy in the range of 5 to 2000 keV to a total concentration level less than 10²²/cm³ at RT and the accelerated 31P+ ions are implanted by using beam energy in the range of 10 to 2000 keV with a total concentration level in the range of 1×1014 cm−3 to 1×10²² cm⁻³ in the range of 1 to 100 K.

7. The method of claim 6 further including the step of wherein the co-doped diamond material exhibits a carrier concentration exceeding 1×10\hat{ }9 cm−3, at room temperature and atmospheric pressure resistivity of less than 1 Mega-Ohm/square, and a room temperature mobility greater than 300 cm²/Vs, as measured by Van der Pauw and Hall effect techniques.

8. The method of claim 1, further including the step of wherein the co-doping process is scalable for large-area diamond substrates, enabling the production of electronic-grade diamond films suitable for integration into commercial semiconductor devices.
